(19) United States
(12) Patent Application Publication
(10) Pub. No.: US 2025/0239523 A1
(43) Pub. Date: Jul. 24, 2025

(54) BACKSIDE POWER SCHEME WITH FRONT-SIDE POWER INPUT

(71) Applicant: Taiwan Semiconductor Manufacturing Co., Ltd., Hsinchu (TW)

(72) Inventors: Chih-Chao Chou, Hsinchu (TW); Cheng-Chi Chuang, New Taipei City (TW); Yi-Hsun Chiu, Zhubei City (TW); Shang-Wen Chang, Jhubei City (TW); Ching-Wei Tsai, Hsinchu (TW)

(21) Appl. No.: 18/666,242

(22) Filed: May 16, 2024

Related U.S. Application Data
(60) Provisional application No. 63/624,505, filed on Jan. 24, 2024.

(51) Int. Cl. H01L 23/528; H01L 21/304; H01L 21/8234; H01L 27/088; H01L 29/06; H01L 29/08; H01L 29/423; H01L 29/786

(52) U.S. Cl. CPC H01L 23/5286; H01L 21/304; H10D 62/151; H10D 84/013; H10D 84/0149; H10D 84/038; H10D 84/83; H10D 30/6735; H10D 30/6757; H10D 62/118

(57) ABSTRACT

A method includes forming integrated circuit devices comprising a transistor formed at a top surface of a semiconductor substrate of a wafer, forming a front-side interconnect structure over and connecting to the integrated circuit devices, forming an electrical connector over and connecting to the front-side interconnect structure, performing a backside grinding process to thin the semiconductor substrate, and forming a backside interconnect structure on a backside of the integrated circuit devices. The backside interconnect structure includes a power delivery network, and is configured to receive a positive power supply voltage from the electrical connector and redistributes the positive power supply voltage to the integrated circuit devices.

### PRIORITY CLAIM AND CROSS-REFERENCE

This application claims the benefit of the following provisionally filed U.S. Patent application: Application No. 63/624,505, filed on Jan. 24, 2024, and entitled “Semiconductor Device with Power Delivery Scheme,” which application is hereby incorporated herein by reference.

### BACKGROUND

Power Delivery Networks (PDNs) are formed in device dies for delivering power to integrated circuits. The PDNs are used to deliver positive power supply voltages (VDD) and electrical grounds to individual devices such as transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-8 illustrate the cross-sectional views of intermediate stages in the formation of a device die including a power delivery network in accordance with some embodiments.

FIG. 9 illustrates a perspective view of a device die including a backside power delivery network and a front-side power input in accordance with some embodiments.

FIG. 10 illustrates a perspective view of a transistor for delivering power from the front side to the backside of a device die in accordance with some embodiments.

FIG. 11 illustrates a package including a device die that includes a power delivery network in accordance with some embodiments.

FIG. 12 illustrates a process flow for forming a device die in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A device die including a backside power delivery network and a front-side power input, and the method of forming the same are provided. In accordance with some embodiments of the present disclosure, a device die is formed, which includes electrical connectors on the front side of the device die for receiving power. The power (VDD and VSS) is conducted to the backside of the device die, and is distributed to the devices from the backside of the device die. By forming the electrical connectors on the front side and forming power delivery network on the backside, the heat dissipation may be improved, and the power may be delivered with smaller voltage drop. It is appreciated that although gate all around (GAA) transistors are used as examples to explain the concept of the present disclosure, other types of transistors such as planar transistors, Fin Field-Effect Transistors (FinFETs), or the like, may also be adopted.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

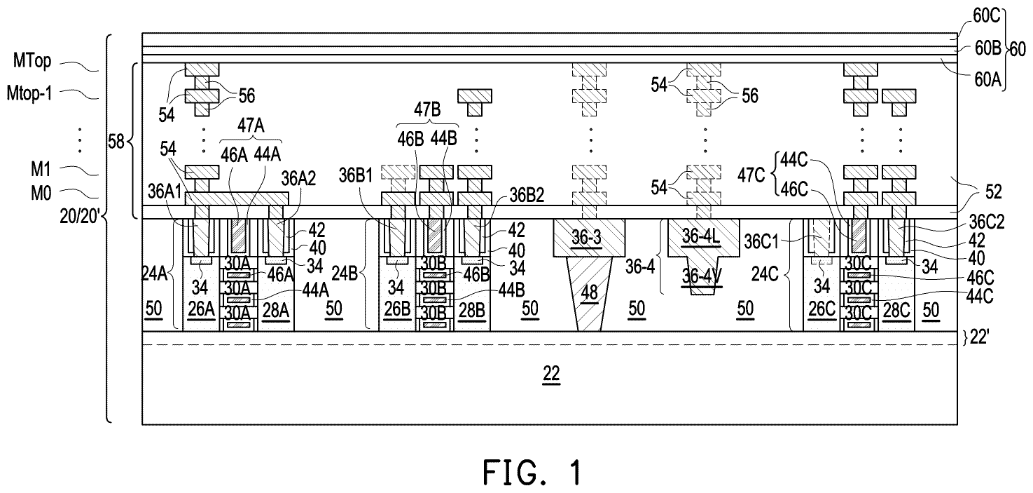

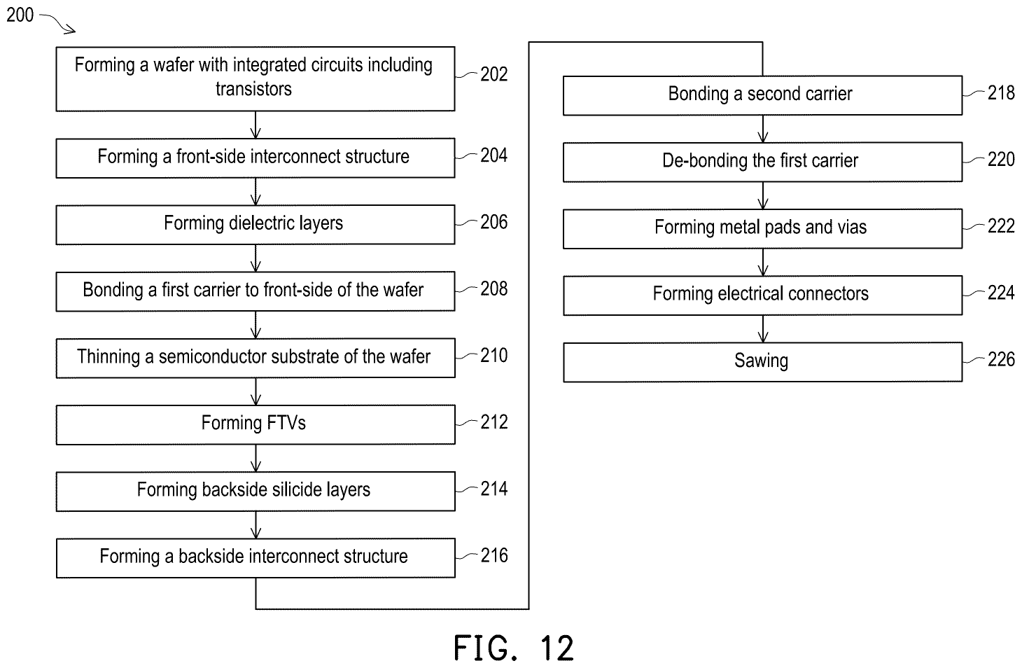

FIGS. 1 through 8 illustrate the cross-sectional views of intermediate stages in the formation of a device die in accordance with some embodiments of the present disclosure. The corresponding processes are also reflected schematically in the process flow shown in FIG. 12.

FIG. 1 illustrates a cross-sectional view in the formation of wafer 20. The respective process is illustrated as process 202 in the process flow 200 as shown in FIG. 12. In accordance with some embodiments, wafer 20 is or comprises a device wafer including active devices and possibly passive devices, which are represented as integrated circuit devices 24. Wafer 20 may include a plurality of chips/dies 20′ therein, with one of chips 20′ being illustrated.

In accordance with some embodiments, wafer 20 includes semiconductor substrate 22. Semiconductor substrate 22 may be formed of or comprise crystalline silicon, crystalline germanium, silicon germanium, carbon-doped silicon, or a III-V compound semiconductor such as GaAsP, AlInAs, AlGaAs, GalInAs, GaInP, GaInAsP, or the like. Shallow Trench Isolation (STI) regions (not shown) may be formed in semiconductor substrate 22 to isolate the active regions in semiconductor substrate 22.

In accordance with some embodiments, integrated circuit devices are formed at the top surface of semiconductor substrate 22, and are collectively referred to as Front-end-of-line (FEOL) structures/devices. The integrated circuit devices may include Complementary transistors, resistors, capacitors, diodes, and/or the like in accordance with some embodiments. The integrated circuit devices include, and are represented by, transistors 24A, 24B, and 24C, which are collectively referred to as integrated circuit devices 24 or transistors 24, depending on the context.

In accordance with some embodiments, integrated circuit devices 24 include transistors 24A, 24B, and 24C. Transistor 24A is a dummy transistor used from conducting power from the front side to the backside of the integrated circuits 24, and its source/drain regions 26A and 28A are interconnected. Transistor 24B has two functions. First, transistor 24B is a power switch, and the power at source/drain region 26B may be conducted to source/drain region 28B at certain time, and may not be conducted to source/drain region 28B at other time. Secondly, transistor 24B is used as a power channel for conducting power from the front side to the backside of the integrated circuit devices 24. The operation of transistor 24B is controlled by signals on the gate electrode 46B to control whether power is connected to the backside the integrated circuit devices 24 through transistor 24B or not.

In accordance with some embodiments, transistors 24A, 24B, and 24C comprise Gate All Around (GAA) transistors. In accordance with alternative embodiments, transistors 24A, 24B, and 24C may be formed of planar transistors, Fin Field-Effect Transistors (FinFETs), Complementary Field-Effect Transistors (CFETs), or the like. In the illustrated examples, GAA transistors are adopted. The structure of transistor 24A is discussed in detail as an example hereinafter, while other transistors may have similar structures.

In accordance with some embodiments, transistor 24A includes channel regions 30A, which may comprise semiconductor nanostructures, and gate stack 47A encircling channel regions 30A. Source/drain regions 26A and 28A are connected to the opposite ends of the channel regions 30A. Source/drain region(s) may refer to a source or a drain, individually or collectively dependent upon the context.

Gate stack 47A includes gate dielectric 44A and gate electrode 46A. Gate dielectric 44A may include an interfacial layer such as a silicon oxide layer, and a high-k dielectric layer on the interfacial layer. The gate electrode 46A includes a plurality of layers, which may include a work function layer, a filling metal layer, and possibly other layers such as a capping layer under the work function layer, and a blocking layer over the work function layer. The work function layer may have a p-type work function material (with a work function higher than about 4.6 eV, for example) when transistor 24A is a p-type transistor or an n-type work function material (with a work function lower than about 4.5 eV, for example) when transistor 24A is an n-type transistor.

In accordance with some embodiments, source/drain regions 26A and 28A may include a semiconductor material. When the respective transistor 24A is a p-type transistor, source/drain regions 26A and 28A may comprise a semiconductor such as silicon, silicon germanium, or the like. A p-type dopant such as boron, indium, or the like may be doped. When the respective transistor 24A is an n-type transistor, source/drain regions 26A and 28A may comprise a semiconductor such as silicon, carbon-doped silicon, or the like. An n-type dopant such as phosphorous, arsenic, antimony, or the like may be doped.

Silicide layers 34 are formed at the top surfaces of source/drain regions 26A and 28A. Contact Etch Stop Layer (CESL) 40 and ILD 42 are formed over source/drain regions 26A and 28A. In accordance with some embodiments, CESL 40 is formed of SiN, SiOC, or the like. ILD 42 is formed of silicon oxide, Phospho Silicate Glass (PSG), Boro Silicate Glass (BSG), Boron-doped Phospho Silicate Glass (BPSG), Fluorine-doped Silicate Glass (FSG), or the like. ILD 42 may be formed using spin coating, Flowable Chemical Vapor Deposition (FCVD), or the like. In accordance with alternative embodiments, ILD 42 may also be formed using a deposition method such as Plasma Enhanced Chemical Vapor Deposition (PECVD), Low Pressure Chemical Vapor Deposition (LPCVD), or the like.

Source/drain contact plugs 36A1 and 36A2 are formed over and contacting silicide layers 34, and penetrate through the CESL 40 and ILD 42. In accordance with some embodiments, contact plugs 36A1 and 36A2 are formed of or comprise a conductive material selected from tungsten, aluminum, copper, titanium, tantalum, titanium nitride, tantalum nitride, alloys therefore, and/or multi-layers thereof. The formation of contact plugs 36A1 and 36A2 may include forming contact openings in ILD 42, filling a conductive material(s) into the contact openings, and performing a planarization process (such as a Chemical Mechanical Polish (CMP) process or a mechanical grinding process) to level the top surfaces of contact plugs 36A1 and 36A2 with the top surface of ILD 42.

Transistors 24B and 24C may be formed in the same processes (or different processes) as the formation of transistor 24A. Each of transistors 24B and 24C may also have a same conductivity type as, or an opposite conductivity type than, transistor 24A. Transistors 24B and 24C may have similar structures as transistor 24, and include the same types of components as transistor 24A. For example, transistors 24B and 24C also include channel regions, source/drain regions, gate stacks, silicide layers, source/drain contact plugs, and the like. The features of transistors 24B and 24C are thus not discussed in detail, and may be found referring to the discussion of transistor 24A.

The features of transistors 24B and 24C are denoted using similar reference notations as the corresponding features of transistor 24A, except that the notations of the features of transistor 24A include postfix “A,” while the notations of the features of transistors 24B and 24C include postfixes “B” and “C,” respectively. The like features of transistors 24A, 24B and 24C may be collectively referred to using the corresponding reference number without the letter “A,” “B,” or “C.” For example, the source/drain regions of transistors 24 (including transistors 24A, 24B and 24C) may be collectively referred to as source/drain regions 26 and 28, and the channel regions are collectively referred to as channel regions 30. The gate dielectrics, gate electrodes, gate stacks of the transistors 23 are thus collectively referred to as gate dielectrics 44, gate electrodes 46, gate stacks 47, and source/drain contact plugs 36.

In accordance with some embodiments, conductive features 36-3 and 36-4 are also formed, and may be formed in same processes as the formation of source/drain contact plugs 36A1, 36A2, 36B1, 36B2, 36C1, and 36C2. Conductive feature 36-4 differs from conductive feature 36-3 in that conductive feature 36-3 has a metal line portion, and does not include any via portion underneath the line portion. Conductive feature 36-4, on the other hand, includes line portion 36-4L and via portion 36-4V. The line portion 36-4L and via portion 36-4V are continuously connected with no distinguishable interface in between, and are formed through a dual damascene process. The bottoms of source/drain contact plugs 36A1 and 36A2 may be at substantially the same level as the bottom surface of metal feature 36-3 and the bottom surface of line portion 36-4L.

Power via 48 may be formed prior to the formation of metal feature 36-3, and the bottom of metal feature 36-3 contacts the top surface of power via 48. Power via 48 may also be formed of a metallic material such as copper, tungsten, cobalt, titanium, titanium nitride, tantalum, tantalum nitride, nickel, or the like, or combinations thereof. The via portion 36-4V may be in contact with a top surface of an underlying dielectric material, which may be a Shallow Trench Isolation (STI) region, ILD 42, or the like.

Transistors 24A, 24B, and 24C, and conductive features 36-3 and 36-4 are separated from each other by regions 50. While the details of regions 50 are not shown, regions 50 may include CESLs, ILDs, STI regions, conductive features for connecting neighboring features, and the like.

Further referring to FIG. 1, a front side interconnect structure 58 is formed as including metal layers and dielectric layers. The respective process is illustrated as process 204 in the process flow 200 as shown in FIG. 12. Interconnect structure 58 further includes dielectric layers 52 (also referred to as Inter-Metal Dielectrics (IMDs)), etch stop layers (not shown), metal lines 54, and vias 56. The metal lines at a same level are collectively referred to as a metal layer hereinafter. In accordance with some embodiments, interconnect structure 58 includes a plurality of metal layers (Mo through Mtop) including metal lines 54 that are interconnected through vias 56. The metal layers in interconnect structure 58 may be denoted as Mo, M1 . . . . Mtop-1, Mtop, and the like.

Metal lines 54 and vias 56 may be formed of copper or copper alloys, and may also be formed of or comprise other metals such as aluminum, tungsten, nickel, or the like. In accordance with some embodiments, dielectric layers 52 comprise low-k dielectric materials. The dielectric constants (k values) of the low-k dielectric materials may be lower than about 3.5 or lower than about 3.0, for example. Dielectric layers 52 may comprise a carbon-containing low-k dielectric material (such as SiOCN), Hydrogen SilsesQuioxane (HSQ),

MethylSilsesQuioxane (MSQ), or the like. The etch stop layers may be formed of or comprise aluminum oxide, aluminum nitride, SiOC, SiON, or the like, or multi-layers thereof. The formation of metal lines 54 and vias 56 in dielectric layers 52 may include single damascene processes and/or dual damascene processes.

In accordance with some embodiments, the total number of metal layers Mo through Mtop may be greater than about 9, and may be in the range between about 9 and 16. In accordance with some embodiments, the top metal layer Mtop is formed in a top dielectric layer of the dielectric layers 52. The top dielectric layer may be formed of or comprise a low-k dielectric material, as discussed above. Alternatively, the top dielectric layer may be formed of or comprise a non-low-k dielectric material such as un-doped Silicate Glass (USG), silicon oxide, silicon oxynitride, silicon nitride, or the like, or multi-layers thereof.

Dielectric layers 60 are then formed over interconnect structure 58. The respective process is illustrated as process 206 in the process flow 200 as shown in FIG. 12. Dielectric layers 60 may include dielectric layers 60A, 60B, and 60C. In accordance with some embodiments, dielectric layer 60A comprises USG, dielectric layer 60B comprises silicon nitride, and dielectric layer 60C comprises silicon oxide (formed through high-density plasma (HDP) Chemical Vapor Deposition (CVD), for example), while other dielectric materials may be used.

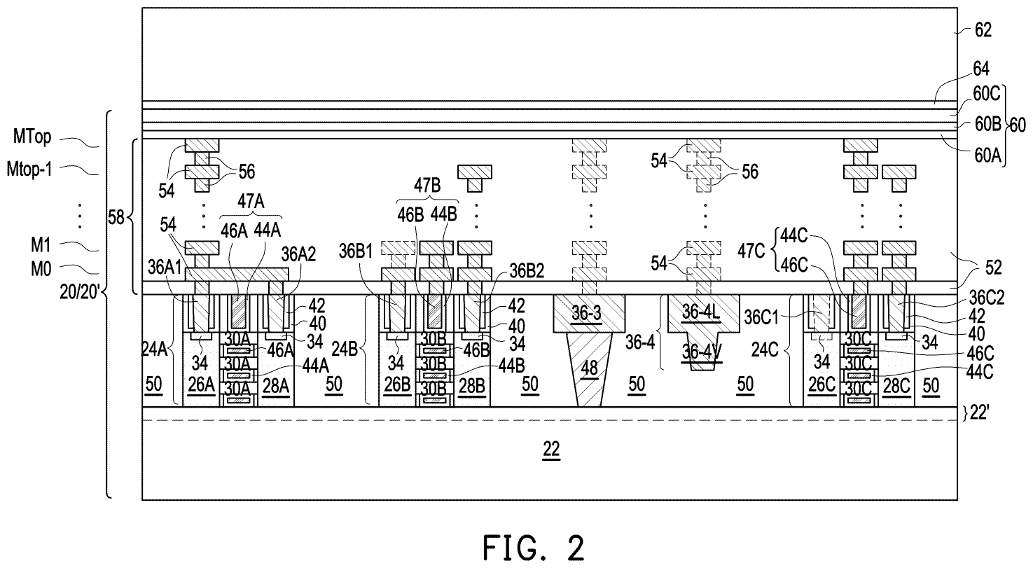

Referring to FIG. 2, carrier 62 is attached to the front side of wafer 20. The respective process is illustrated as process 208 in the process flow 200 as shown in FIG. 12. In accordance with some embodiments, carrier 62 may be a blank wafer. The blank wafer may be a blank silicon wafer. Bond layer 64 in accordance with these embodiments may be used to bond the silicon wafer to wafer 20. In accordance with some embodiments, bond layer 64 may be formed of a silicon-containing dielectric material such as SiO, SiC, SiOC, SiON, SiOCN, or the like.

In accordance with alternative embodiments, carrier 62 comprises a glass carrier, which may be attached to wafer 20 through an adhesive 64. Adhesive 64 may be a light-to-heat-Conversion (LTHC) material, which is configured to be decomposed under the heat of light (such as a laser beam).

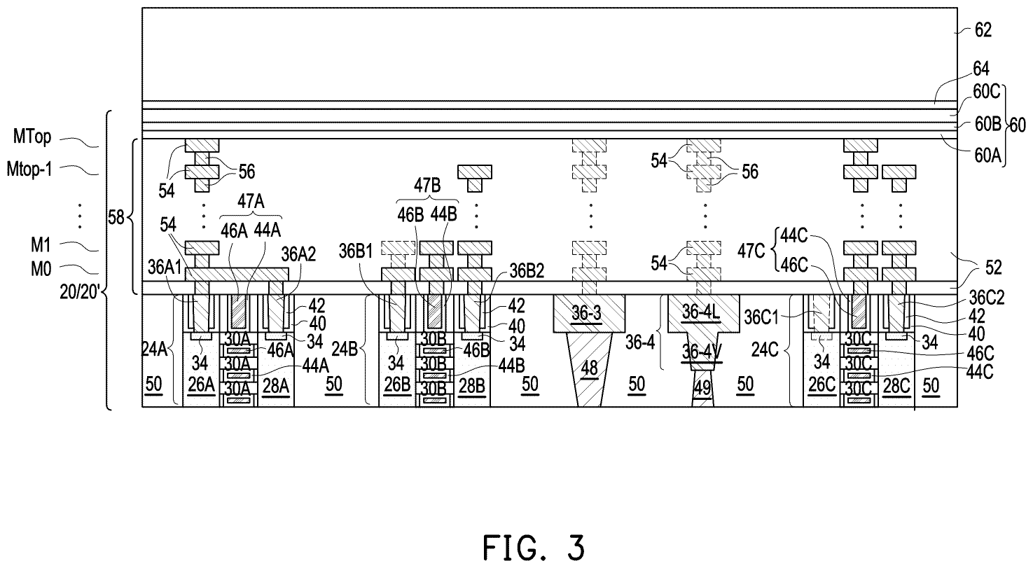

FIG. 3 illustrates the backside thinning of semiconductor substrate 22 in accordance with some embodiments. The respective process is illustrated as process 210 in the process flow 200 as shown in FIG. 12. The backside thinning process may be performed through a CMP process, a mechanical grinding process, or the like. In accordance with some embodiments, as shown in FIG. 3, semiconductor substrate 22 (FIG. 2) is fully removed, and the bottom surfaces of the source/drain regions 26 and 28 of transistors 24 are revealed. The backside thinning process may be performed using gate dielectrics 44 as a stop layer. Alternatively, other features such as source/drain regions 26 and 28 or power vias 48 may be used as the stop layer. The bottom surface of power via 48 may also be revealed.

In accordance with alternative embodiments, the backside thinning process may be performed with a thin layer of semiconductor substrate 22 being left. For example, the portion 22′ as shown in FIG. 2 may be left without being removed. In accordance with these embodiments, the subsequently formed conductive features such as vias penetrate through the remaining semiconductor substrate 22. Dielectric isolation layers are also formed to encircle the conductive features to electrically insulate the conductive features from the remaining semiconductor substrate portion 22′, if any left.

In addition, Feed-Through Via (FTV) 49 is formed from the backside of wafer 20 to electrically connect to conductive feature 36-4. The respective process is illustrated as process 212 in the process flow 200 as shown in FIG. 12. The formation process may include etching the dielectric layer(s) in regions 50 to form an opening, filling the opening with a conductive material, and performing a planarization process such as a CMP process or a mechanical grinding process. The etched portions of regions 50 may be a part of an STI region or portions of the CESL 40 and ILD 42. FTV 49 lands on the bottom surface of via portion 36-4V, which is used as an etch stop layer in the etching process.

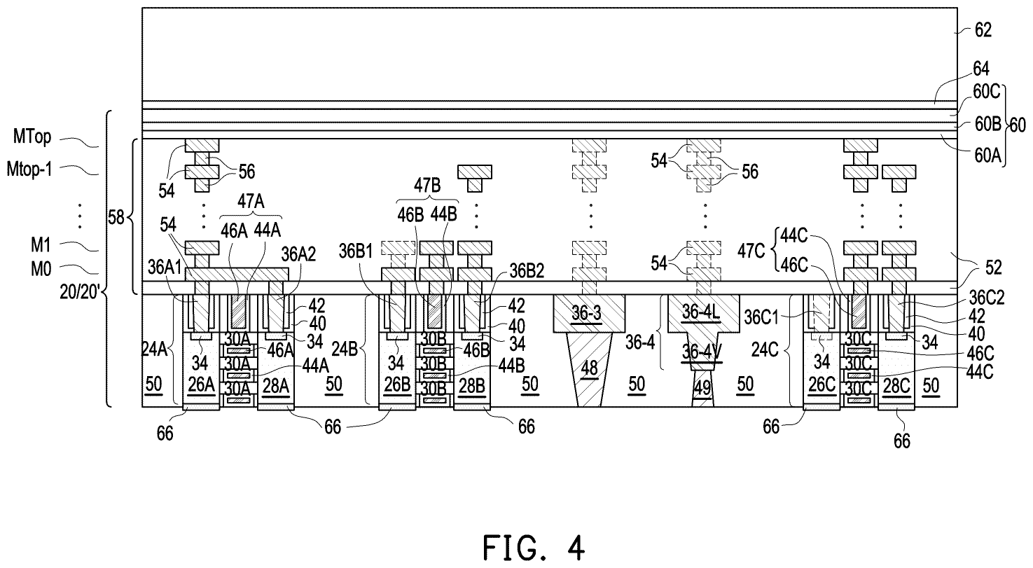

FIG. 4 illustrates the formation of backside silicide layers 66 on the bottom surfaces of source/drain regions 26 and 28. The respective process is illustrated as process 214 in the process flow 200 as shown in FIG. 12. In accordance with some embodiments, a metal such as titanium, cobalt, or the like is deposited on the back surface of wafer 20. An anneal process is then performed to react the metal layer with the bottom surface portions of the source/drain regions 26 and 28 to form metal silicide layers 66. Unreacted portions of the metal layer are then removed in an etching process. The order of the formation of FTV 49 and backside silicide layers 66 may be inversed.

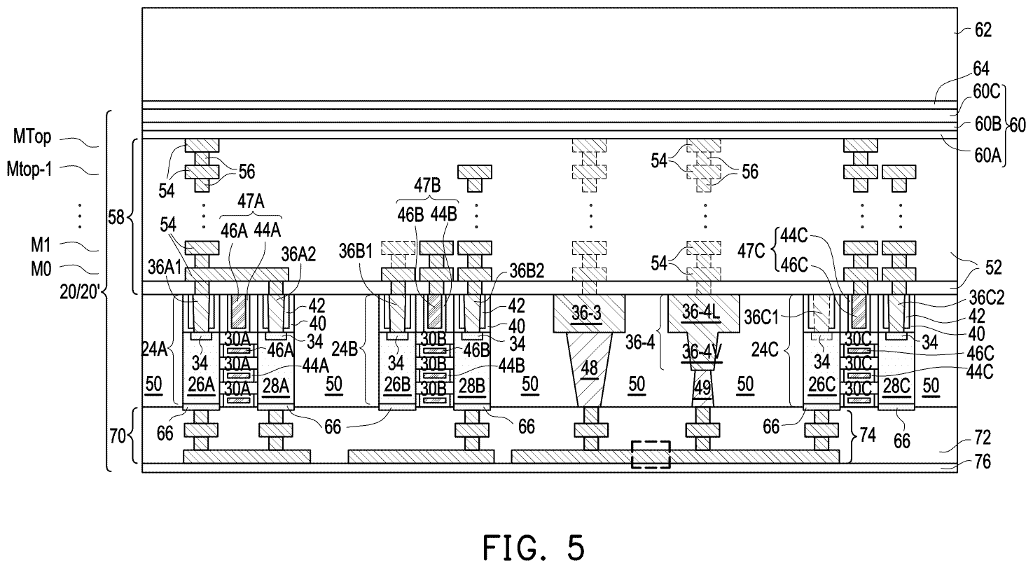

Referring to FIG. 5, backside redistribution structure 70 is formed. The respective process is illustrated as process 216 in the process flow 200 as shown in FIG. 12. Backside redistribution structure 70 includes dielectric layers 72, and Redistribution Lines (RDLs) 74 formed in dielectric layers 72. Dielectric layers 72 may be formed of organic dielectric materials such as polyimide, PBO, BCB, or the like, or inorganic dielectric materials such as silicon oxide, silicon nitride, silicon oxycarbide, silicon oxynitride, USG, or the like.

RDLs 74 may be formed of or comprise aluminum, copper, nickel, tungsten, titanium, or the like. In accordance with some embodiments, the formation of a layer of RDLs 74 may include forming a dielectric layer 72, etching the respective dielectric layer 72 to form openings, plating a metal seed layer extending into the openings, forming a patterned plating mask, with some portions of the metal seed layer being exposed, and plating to form the RDLs 74. In accordance with alternative embodiments, RDLs 74 may be formed through damascene processes.

RDLs 74 form a backside Power Delivery Network (PDN) (also referred to as backside PDN 74 hereinafter), which is used to electrically connect power supply voltages (including VDD and VSS (electrical ground)) to the integrate circuit devices 24. For example, RDLs 74 electrically connect power from source/drain regions 26A, 28A, and 28B to the signal transistors in the integrated circuit devices 24, which signal transistors are represented by transistor 24C.

In accordance with some embodiments, RDLs 74 conduct the power supply voltages to silicide layers 66 of signal transistors 24C, so that the source/drain regions of transistors 24 to be connected to power (VDD or VSS) may received the power from the bottom sides of the corresponding source/drain regions 26 and 28. The illustrated RDLs 74 represent the routing of both of VDD routing and VSS routing. It is also appreciated that RDLs 74 are illustrated schematically, and more details of the power delivery scheme are discussed in subsequent paragraphs.

After the formation of the backside interconnect structure 70, bond layer 76 is formed. Bond layer 76 may be used for isolating moisture from reaching backside RDLs 74, and is also used for bonding to a carrier. In accordance with some embodiments, bond layer 76 may be formed of a silicon-containing dielectric material such as SiO, SiC, SiOC, SiON, SiOCN, or the like.

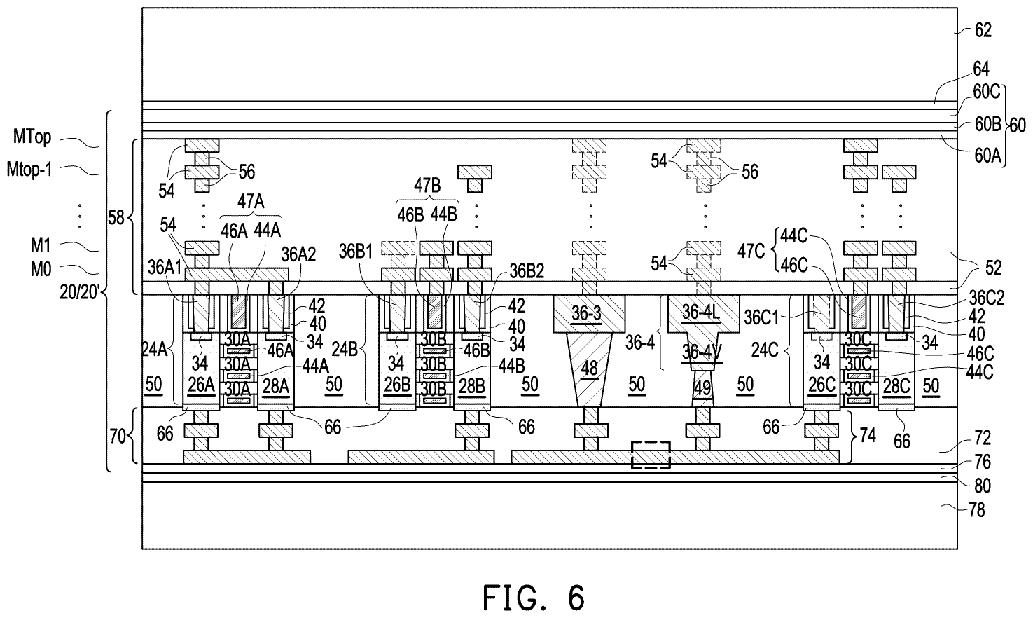

Referring to FIG. 6, carrier 78 is bonded to wafer 20 through bond layers 76 and 80. The respective process is illustrated as process 218 in the process flow 200 as shown in FIG. 12. In accordance with some embodiments, carrier 78 may be a supporting substrate, which may be a blank silicon substrate in accordance with some embodiments. The supporting substrate may be formed of a homogeneous material such as silicon, and there is no other material other than the homogeneous material in the supporting substrate. Bond layer 80 is formed on carrier 78 to bond carrier 78 to bond layer 76. Bond layer 80 may comprise a silicon-containing dielectric material such as SiO, SiC, SiOC, SiON, SiOCN, or the like. The bonding may include fusion bonding.

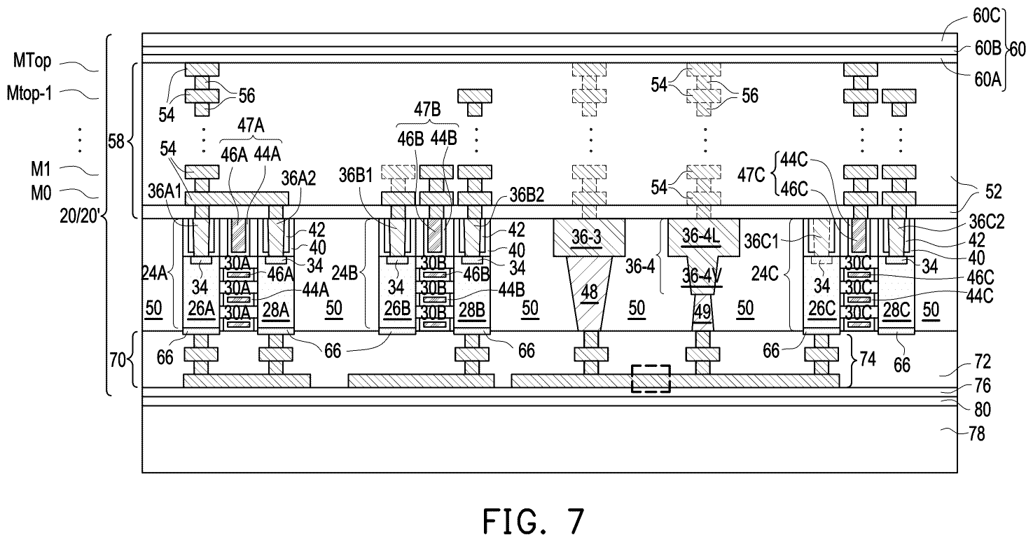

In a subsequent process, carrier 62 is de-bonded. The respective process is illustrated as process 220 in the process flow 200 as shown in FIG. 12. When carrier 62 is a glass carrier adhered to the underlying structure through an LTHC, a laser beam may be used to decompose the LTHC, thus de-bonding carrier 62. When carrier 62 is a silicon wafer bonding to wafer 20 through fusion bonding, carrier 62 may be removed, for example, in a CMP process, a mechanical grinding process, an etching process, and/or a process including implanting and annealing. The resulting structure is shown in FIG. 7, in which dielectric layers 60 are exposed.

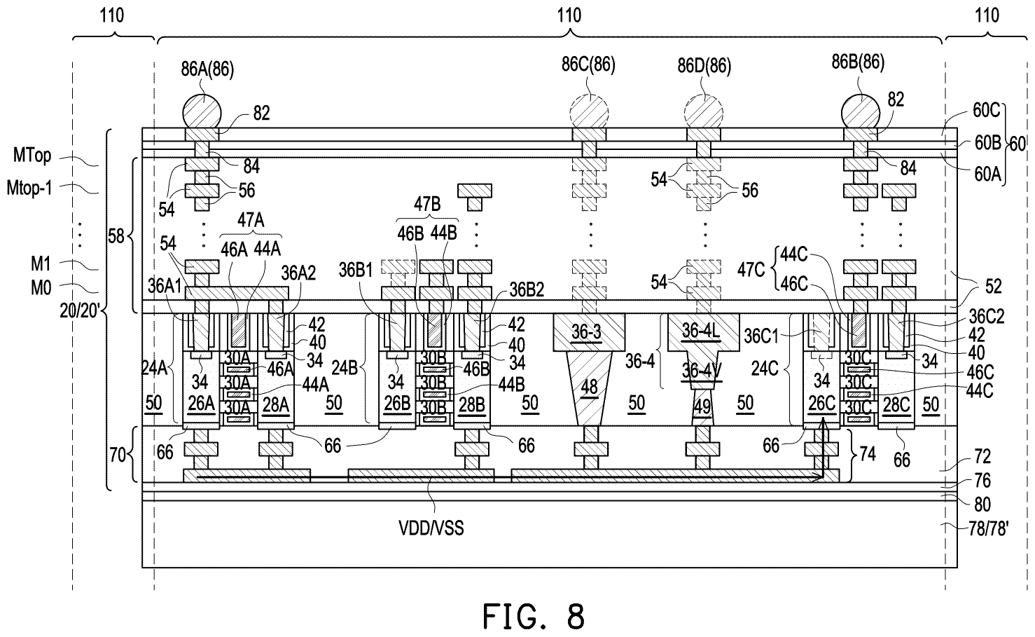

Next, as shown in FIG. 8, metal pads 82 and vias 84 are formed. The respective process is illustrated as process 222 in the process flow 200 as shown in FIG. 12. In accordance with some embodiments, vias 84 are formed in dielectric layers 60B and 60A, and metal pads 82 are formed in dielectric layer 60C. The formation process may include a dual damascene process, wherein via openings are formed in dielectric layers 60B and 60A, and trenches are formed in dielectric layer 60C. A conductive material may be filled into the via openings and trenches, followed by a planarization process to remove excess conductive materials.

Further referring to FIG. 8, electrical connectors 86 (including power electrical connectors 86A and signal electrical connectors 86B) are formed. The respective process is illustrated as process 224 in the process flow 200 as shown in FIG. 12. In accordance with some embodiments, electrical connectors 86 include solder regions, which may be formed by plating solder balls on the metal pads 82, and reflowing the solder balls. In accordance with alternative embodiments, electrical connectors 86 comprise non-reflowable (non-solder) metallic materials. For example, electrical connectors 86 may be formed as a copper pillars, and may or may not include nickel capping layers. Some of the electrical connectors 86 are shown as being dashed to indicate that these electrical connectors 86 may be, or may not be, formed.

The structure in FIG. 8 is then singulated into a plurality of identical packages 110 through a sawing process. The respective process is illustrated as process 226 in the process flow 200 as shown in FIG. 12. In accordance with some embodiments when carrier 78 is a silicon supporting substrate, and is bonded to wafer 20 through fusion bonding, carrier 78 may remain on wafer 20 when singulated. Accordingly, the separated device dies 20′ are attached to the sawed pieces 78′ (referred to as supporting substrates 78′) of carrier 78. Supporting substrates 78′ may help the heat dissipation in the final package when device die 20′ is powered up.

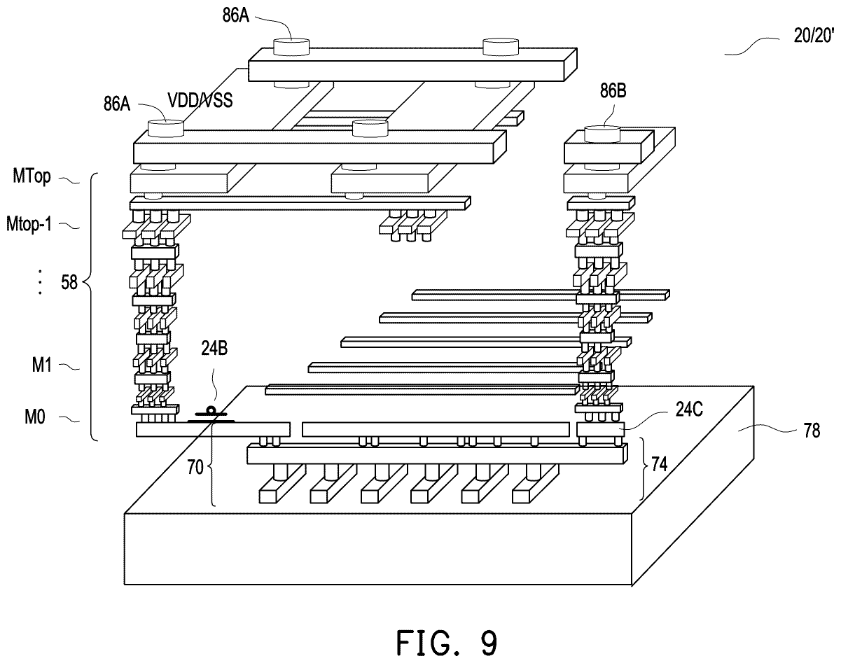

FIG. 9 illustrates a perspective view of wafer 20 (and device die 20′) in accordance with some embodiments. Electrical connectors 86A receive power supply voltages, and conduct the power supply voltages VDD and VSS to the underlying metal lines in metal layers Mo through Mtop. The power supply voltages may be conducted to the backside RDLs 74, which redistribute power to the integrated circuit devices such as transistors.

Transistor 24B acts as a power switch for gating power. FIG. 9 also illustrates that signal electrical connector 86B is used to receive signals, and conduct the signals to transistor 24C for further processing.

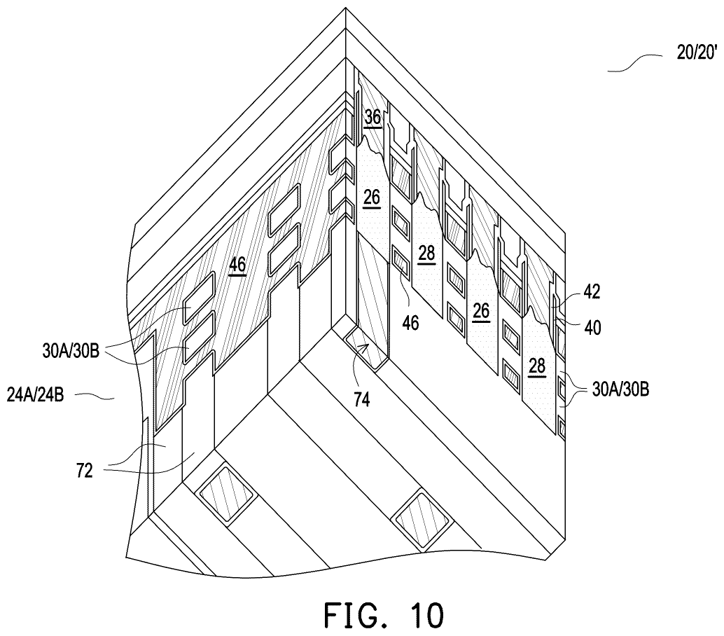

FIG. 10 illustrates a perspective view of a portion of device die 20′ in accordance with some embodiments. The illustrated portion includes transistor 24A or 24B, which includes channels (semiconductor nanostructures) 30A or 30B, and gate electrode 46 encircling channels 30. Via 74, which is a part of RDLs 74, is connected to the backside of source/drain region 26, and is used for conducting power from the front side to the backside of transistor 24A/24B.

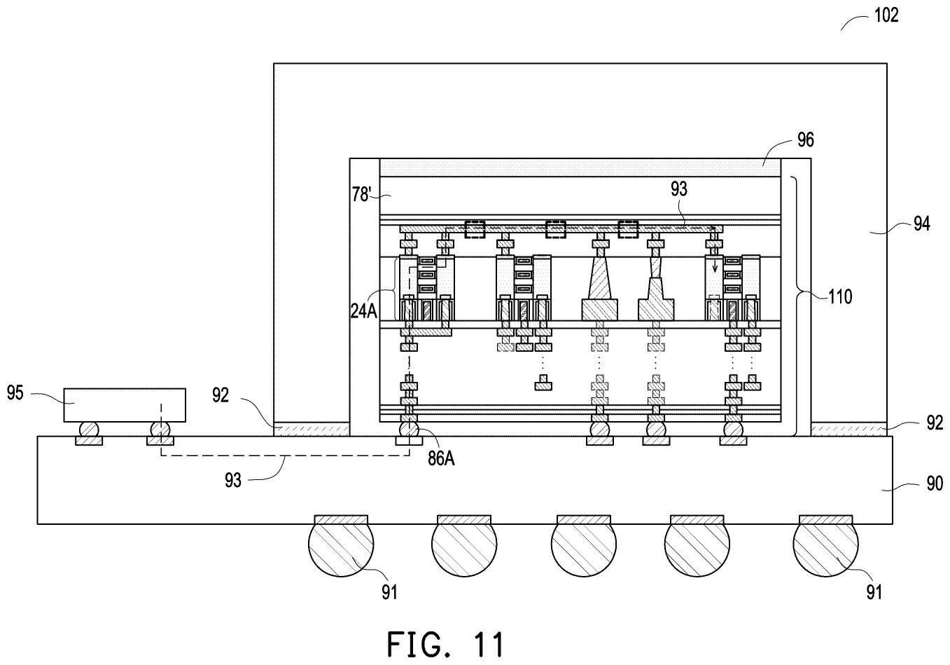

FIG. 11 illustrates a package 102 including device die 20′ in accordance with some embodiments. Device die 20′ is bonded to package component 90. Package component 90 may be a silicon interposer, an organic interposer, a package substrate, a printed circuit board, a package, or the like. Power VDD and VSS may be provided to the electrical connectors 91 of package component 90, and conducted to electrical connector 86A of device die.

In accordance with some embodiments, FIG. 11 schematically illustrates power chip 95, which is bonded to package component 90. Power chip 95 may be used to convert power, for example, from a high power supply voltage such as 12V, 3.3V, or the like to a lower power supply voltage such as 1.2V and/or 0.9V, and conduct the lower power supply voltage to electrical connector 86A through conductive path 93. The power may be gated by transistor 24B, and the gated power VDD and the ungated power are provided to some integrated circuits. Ungated power may be conducted to the backside PDN through dummy transistor 24A (FIG. 8) and conductive features 36-3 and 36-4.

In accordance with some embodiments, heat sink 94 is attached to package component 90 through adhesive 92. The heat sink 94 may also be attached to device die 20′ through thermal interface material 96, which is further adhered to supporting substrate 78′.

Referring back to FIG. 8, the power supply voltages, which are received from electrical connectors 86A, 86C, and 86D, are conducted to the metal lines 54 and vias 56, and then conducted to the backside of transistors 24C (with one transistor 24C illustrated) through transistors 24A and 24B. The power supply voltage may also be conducted to the backside of transistors 24C through a first conductive path comprising conductive features 36-3 and power via 48, and a second conductive path comprising conductive feature 36-4 and FTV 49.

In accordance with some embodiments, transistor 24A is a dummy transistor, whose source/drain regions 26A and 28A are interconnected, and are connected in parallel to conduct power. The gate stack 47A of dummy transistor 24A may be electrically floating. For example, the entire top surface of dummy transistor 24A may be in physical contact with a dielectric material such as dielectric layer 52.

Transistor 24B, on the other hand, may be an active transistor acting as a power switch. For example, the source/drain region 26B of transistor 24B is connected to a power supply node (VDD or VSS). Transistor 24B is also referred to as a gating transistor (a power switch), which is configured to receive a power (such as a true VDD (TVDD)) at source/drain region 26B. Depending on the signal received at the gate electrode 46B of transistor 24B, transistor 24B may conduct the TVDD voltage to source/drain region 28B, which voltage is referred to as a virtual VDD (VVDD), or may cut the conduction, so that the power is not conducted to some parts (but not all) of the backside PDN 74. In accordance with some embodiments, on the front side of source/drain region 28B, there may not be silicide layer formed, and there may not be source/drain contact plug formed. In accordance with these embodiments, an entirety of the top surface of source/drain region 28B may be in contact with a dielectric feature such as CESL 40.

Transistor 24C may be an active transistor, and is not used for conducting power from front side to the backside PDN 74. The power may be connected to the backside of source/drain region 26C from the backside PDN 74. In accordance with some embodiments, on the front side of source/drain region 26C, there may not be silicide layer formed, and there may not be source/drain contact plug formed. An entirety of the top surface of source/drain region 26C may contact a dielectric feature such as CESL 40. In accordance with alternative embodiments, the power voltage provided to source/drain region 26C from backside may be further conducted to the front side of transistor 24, for example, to a nearby transistor(s) or other devices. Accordingly, the corresponding silicide layer 34 and source/drain contact plug 36C1 are illustrated as being dashed to indicate that these features may or may not be formed.

In accordance with some embodiments, transistor 24C inputs or outputs signals, for example, through source/drain region 28C and source/drain contact plug 36C2. source/drain region 28C may be connected to electrical connector 86B in accordance with some embodiments.

Since the gates of the active transistors are on the front side, power or signals are connected to the gates of the active transistors such as 24C from the front side. The power is also received from electrical connectors 86A, 86C, and 86D. Since majority of the power is routed to the backside of transistors, the routing of power on the front side may be reduced, for example, with only metal layers Mo and M1 being used for lateral power routing to transistors, while the upper metal layers are not used for lateral power routing. This releases some front side chip area for signal routing.

In accordance with some embodiments, throughout the entire device die 20′, no signal is conducted to the backside of transistors, and the backside is solely used for conducting power. Moving power routing to backside avoids the competition of the power routing with signal routing. The signal routing on the front side is easier. The power lines on the backside may be formed wider. This results in reduced voltage drop.

The conductive path comprising conductive features 36-3 and power via 48, and the conductive path comprising conductive feature 36-4 and FTV 49 may also be used for conducting power. In accordance with some embodiments, conductive features 36-3 and 36-4 receives power from electrical connectors 86C and 86D, respectively. In accordance with alternative embodiments, connectors 86C and 86D are not formed, and conductive features 36-3 and 36-4 receives power from electrical connector 86A (along with transistors 24A and 24B) instead.

Electrical connector 86B may be used for receiving/outputting signals. Electrical connector 86B may be connected directly to transistor 24C, or provide signal to other circuits, which eventually provide signals to transistor 24C.

The embodiments of the present disclosure have some advantageous features. By receiving power and signals from the front side of device dies, the backside of the device die may be joined with a carrier, which helps the heat dissipation. Also, by moving power routing to the backside of the device die, since the backside does not have signal routing, there are more spaces for routing power, and the power lines may be made wider, and the voltage drop is smaller.

In accordance with some embodiments of the present disclosure, a method comprises forming integrated circuit devices comprising a first transistor, wherein the first transistor is formed at a top surface of a semiconductor substrate of a wafer; forming a front-side interconnect structure over and connecting to the integrated circuit devices; forming a first electrical connector over and connecting to the front-side interconnect structure; performing a backside grinding process to thin the semiconductor substrate; and forming a backside interconnect structure on a backside of the integrated circuit devices, wherein the backside interconnect structure comprises a power delivery network, and the power delivery network is configured to receive a positive power supply voltage from the first electrical connector and redistributes the positive power supply voltage to the integrated circuit devices.

In an embodiment, the method further comprises bonding a blanket carrier to the wafer, wherein the blanket carrier is on the backside of the integrated circuit devices; and sawing the wafer and the blanket carrier into a plurality of packages. In an embodiment, the method further comprises bonding a front side of one of the plurality of packages to a package component; and attaching a heat sink to a piece of the blanket carrier in the one of the plurality of packages. In an embodiment, the method further comprises epitaxially growing an epitaxy semiconductor region, wherein the power delivery network is electrically connected to the first electrical connector through the epitaxy semiconductor region.

In an embodiment, the epitaxy semiconductor region is a source/drain region of a transistor in the integrated circuit devices. In an embodiment, the transistor is a power switch comprising a gate and an additional source/drain region, and wherein the power switch is configured to turn on or off a connection between the source/drain region and the additional source/drain region. In an embodiment, the transistor is a dummy transistor that further comprises a gate and an additional source/drain region, and wherein the power delivery network is electrically connected to the first electrical connector through both of the source/drain region and the additional source/drain region.

In an embodiment, the method further comprises forming a metallic feature connecting the first electrical connector to the power delivery network. In an embodiment, the method further comprises forming a second electrical connector over and connecting to the front-side interconnect structure, wherein the second electrical connector is a signal node. In an embodiment, the method further comprises forming a signal transistor comprising forming an additional source/drain region; and forming a source/drain silicide layer on a backside of the additional source/drain region, wherein the power delivery network is connected to the additional source/drain region through the source/drain silicide layer.

In accordance with some embodiments of the present disclosure, a structure comprises a device die comprising a plurality of integrated circuit devices; a front-side interconnect structure over and connecting to the integrated circuit devices; an electrical connector over the front-side interconnect structure; and a backside interconnect structure on a backside of the integrated circuit devices, wherein the backside interconnect structure comprises a power delivery network electrically connecting the electrical connector to backsides of the integrated circuit devices.

In an embodiment, the structure further comprises a transistor comprising a first source/drain region, wherein the first source/drain region electrically connects the electrical connector to the power delivery network. In an embodiment, the transistor further comprises a second source/drain region, wherein the transistor is configured to turn on or turn off a connection from the first source/drain region to the second source/drain region in response to a signal on a gate of the transistor. In an embodiment, the transistor further comprises a second source/drain region electrically shorted to the first source/drain region, wherein the second source/drain region further electrically connects the electrical connector to the power delivery network.

In an embodiment, the structure further comprises a signal transistor comprising a source/drain region; and a source/drain silicide layer on a backside of the source/drain region, wherein the power delivery network is electrically connected to the source/drain region through the source/drain silicide layer. In an embodiment, the structure further comprises a carrier bonding to a backside of the device die. In an embodiment, the structure further comprises a heat sink attached to the carrier.

In accordance with some embodiments of the present disclosure, a structure comprises a plurality of transistors comprising a first transistor comprising a first source/drain region; and a second source/drain region, wherein the first transistor acts as a power switch configured to turn on or off a connection between the first source/drain region and the second source/drain region; a second transistor comprising a third source/drain region; and a fourth source/drain region, wherein the second transistor is a signal transistor configured to receive a signal; a front-side interconnect structure on a front side of the plurality of transistors; an electrical connector over the front-side interconnect structure, wherein the electrical connector is electrically connected to the first source/drain region; and a backside interconnect structure on a backside of the plurality of transistors, wherein the backside interconnect structure electrically connects the second source/drain region to the third source/drain region.

In an embodiment, the structure further comprises a first silicide layer on a backside of the second source/drain region; and a second silicide layer on a backside of the third source/drain region, wherein the backside interconnect structure electrically connects the second source/drain region to the third source/drain region through the first silicide layer and the second silicide layer. In an embodiment, the first transistor is configured to deliver a power received from the electrical connector into the first source/drain region, and deliver the power from the second source/drain region to the backside interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming integrated circuit devices comprising a first transistor, wherein the first transistor is formed at a top surface of a semiconductor substrate of a wafer;
forming a front-side interconnect structure over and connecting to the integrated circuit devices;
forming a first electrical connector over and connecting to the front-side interconnect structure;
performing a backside grinding process to thin the semiconductor substrate; and
forming a backside interconnect structure on a backside of the integrated circuit devices, wherein the backside interconnect structure comprises a power delivery network, and the power delivery network is configured to receive a positive power supply voltage from the first electrical connector and redistributes the positive power supply voltage to the integrated circuit devices.

2. The method of claim 1 further comprising:
bonding a blanket carrier to the wafer, wherein the blanket carrier is on the backside of the integrated circuit devices; and
sawing the wafer and the blanket carrier into a plurality of packages.

3. The method of claim 2 further comprising:
bonding a front side of one of the plurality of packages to a package component; and
attaching a heat sink to a piece of the blanket carrier in the one of the plurality of packages.

4. The method of claim 1 further comprising epitaxially growing an epitaxy semiconductor region, wherein the power delivery network is electrically connected to the first electrical connector through the epitaxy semiconductor region.

5. The method of claim 4, wherein the epitaxy semiconductor region is a source/drain region of a transistor in the integrated circuit devices.

6. The method of claim 5, wherein the transistor is a power switch comprising a gate and an additional source/drain region, and wherein the power switch is configured to turn on or off a connection between the source/drain region and the additional source/drain region.

7. The method of claim 5, wherein the transistor is a dummy transistor that further comprises a gate and an additional source/drain region, and wherein the power delivery network is electrically connected to the first electrical connector through both of the source/drain region and the additional source/drain region.

8. The method of claim 1 further comprising forming a metallic feature connecting the first electrical connector to the power delivery network.

9. The method of claim 1 further comprising forming a second electrical connector over and connecting to the front-side interconnect structure, wherein the second electrical connector is a signal node.

10. The method of claim 1 further comprising forming a signal transistor comprising:
forming an additional source/drain region; and
forming a source/drain silicide layer on a backside of the additional source/drain region, wherein the power delivery network is connected to the additional source/drain region through the source/drain silicide layer.

11. A structure comprising:
a device die comprising:
a plurality of integrated circuit devices;
a front-side interconnect structure over and connecting to the integrated circuit devices;
an electrical connector over the front-side interconnect structure; and
a backside interconnect structure on a backside of the integrated circuit devices, wherein the backside interconnect structure comprises a power delivery network electrically connecting the electrical connector to backsides of the integrated circuit devices.

12. The structure of claim 11 further comprising a transistor comprising a first source/drain region, wherein the first source/drain region electrically connects the electrical connector to the power delivery network.

13. The structure of claim 12, wherein the transistor further comprises a second source/drain region, wherein the transistor is configured to turn on or turn off a connection from the first source/drain region to the second source/drain region in response to a signal on a gate of the transistor.

14. The structure of claim 12, wherein the transistor further comprises a second source/drain region electrically shorted to the first source/drain region, wherein the second source/drain region further electrically connects the electrical connector to the power delivery network.

15. The structure of claim 11 further comprising a signal transistor comprising:
a source/drain region; and
a source/drain silicide layer on a backside of the source/drain region, wherein the power delivery network is electrically connected to the source/drain region through the source/drain silicide layer.

16. The structure of claim 11 further comprising a carrier bonding to a backside of the device die.

17. The structure of claim 16 further comprising a heat sink attached to the carrier.

18. A structure comprising:
a plurality of transistors comprising:
a first transistor comprising:
a first source/drain region; and
a second source/drain region, wherein the first transistor acts as a power switch configured to turn on or off a connection between the first source/drain region and the second source/drain region;
a second transistor comprising:
a third source/drain region; and
a fourth source/drain region, wherein the second transistor is a signal transistor configured to receive a signal;
a front-side interconnect structure on a front side of the plurality of transistors;
an electrical connector over the front-side interconnect structure, wherein the electrical connector is electrically connected to the first source/drain region; and
a backside interconnect structure on a backside of the plurality of transistors, wherein the backside interconnect structure electrically connects the second source/drain region to the third source/drain region.

19. The structure of claim 18 further comprising:
a first silicide layer on a backside of the second source/drain region; and
a second silicide layer on a backside of the third source/drain region, wherein the backside interconnect structure electrically connects the second source/drain region to the third source/drain region through the first silicide layer and the second silicide layer.

20. The structure of claim 18, wherein the first transistor is configured to deliver a power received from the electrical connector into the first source/drain region, and deliver the power from the second source/drain region to the backside interconnect structure.
